(19) United States
(12) Patent Application Publication
(10) Pub. No.: US 2019/0239359 A1
(43) Pub. Date: Aug. 1, 2019

(54) PRINTED CIRCUIT BOARD CONNECTING STRUCTURE AND BOND METHOD OF THE SAME

(71) Applicants: Interface Technology (ChengDu) Co., Ltd., Sichuan (CN); Interface Optoelectronics (ShenZhen) Co., Ltd., Guangdong (CN); General Interface Solution Limited, Miaoli County (TW)

(72) Inventor: Shuenn-Ching WANG, Guangdong (CN)

(21) Appl. No.: 15/947,858

(22) Filed: Apr. 8, 2018

(30) Foreign Application Priority Data
Jan. 30, 2018 (CN) 201810089409.3

(51) Int. Cl. H05K 3/32; H05K 3/36

(52) U.S. Cl. CPC H05K 3/323; H05K 3/36

(57) ABSTRACT

The present disclosure provides a printed circuit board connecting structure including a first printed circuit board, a protection layer, an ACF (anisotropy conductive film), and a second printed circuit board. The first printed circuit board includes a first circuit. The protection layer covers a first area of the first circuit. The ACF covers a second area of the first circuit and extending to the protection layer. The second printed circuit board includes a second circuit facing the first circuit. The second printed circuit board partially overlaps with the ACF on the second area of the first circuit, and there is a gap between the second printed circuit board and the protection layer.

### CROSS-REFERENCE TO RELATED APPLICATION

This application claims priority to Chinese Application Serial Number 201810089409.3, filed Jan. 30, 2018, which is herein incorporated by reference.

### BACKGROUND

### Field of Invention

The present invention relates to a printed circuit board connecting structure and a bonding method of the same.

### Description of Related Art

In the convention design of a thin film sensor, the circuit of the sensor has to be protected from environmental air, steam, or debris, and thus a polymer material may be used to form a protection layer on the circuit. However, at a junction between a system printed circuit board (PCB) and an external PCB, a peripheral part of the circuits of the two PCB will be exposed so as to connect with each other.

Taking material and manufacturing registration issue into consideration, some parts of the circuits of the two foregoing PCB are inevitably exposed. A tradition way to overcome the aforementioned problem is to add some protective materials on the exposed parts of the circuit. However, the aforementioned method involves addition steps and cost in the manufacturing steps.

### SUMMARY

The disclosure provides a printed circuit board connecting structure including a first printed circuit board, a protection layer, an anisotropy conductive film (ACF), and a second printed circuit board. The first printed circuit board has a first circuit. The protection layer covers a first area of the first circuit. The ACF covers a second area of the first circuit and extends to the protection layer. The second printed circuit board has a second circuit facing the first circuit, and partially overlaps with the ACF on the second area of the first circuit, in which there is a gap between the second printed circuit board and the protection layer.

In some embodiments, the second area of the first circuit extends to a side of the first printed circuit board.

In some embodiments, an orthogonal projection of the second printed circuit board on the first printed circuit board is spaced apart from the protection layer at a distance.

In some embodiments, the protection layer is located between the ACF and the first area of the first circuit.

In some embodiments, the ACF is located between the second circuit and the second area of the first circuit.

In some embodiments, the ACF is made of a material including thermosetting resin.

Another aspect of the disclosure provides a method of bonding printed circuit board. The method includes disposing a protection layer on a first printed circuit board to cover a first area of a first circuit of the first printed circuit board and expose a second area of the first circuit; using an ACF to cover the second area of the first circuit to enable the ACF to extend to the protection layer; and disposing a second printed circuit board on the ACF on the second area of the first circuit, wherein the second printed circuit board has a second circuit facing towards the first circuit, and there is a gap between the second printed circuit board and the protection layer.

In some embodiments, the method further includes using a thermal head to press the second printed circuit board on the ACF.

In some embodiments, the method further includes using the thermal head to cover the ACF on the protection layer.

In some embodiments, the method further includes using the thermal head to cover the ACF layer between the protection layer and the second printed circuit board.

In sum, the present disclosure provides a printed circuit board connecting structure and manufacturing method of the same. By disposing an ACF between the first printed circuit board and the second circuit board, the first printed circuit board is fixed to the second printed circuit board, and the two are electrically connected. In addition, by setting a gap between the second printed circuit board and the protection layer, the assembling issue induced by the registration requirement is solved. Since the ACF extends to the first circuit in the gap and extends on the protection layer, exterior materials is not able to reach the first circuit of the first printed circuit board via passing between the ACF and the protection layer, and the first circuit of the first printed circuit board is no longer exposed in the environment.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 illustrates a top view of a printed circuit board connecting structure according to an embodiment of the present disclosure;

FIG. 2 illustrates a cross-sectional view along line 2-2 in FIG. 1;

FIG. 3, which illustrates a cross-sectional view along line 3-3 in FIG. 1;

FIG. 4 illustrates a flow diagram of a method of bonding printed circuit board connecting structure shown in FIG. 1; and

FIG. 5A to FIG. 5D illustrates a cross-sectional view of the printed circuit board connecting structure shown in FIG. 1 along line 2-2 in various steps of the method 200 shown in FIG. 4.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

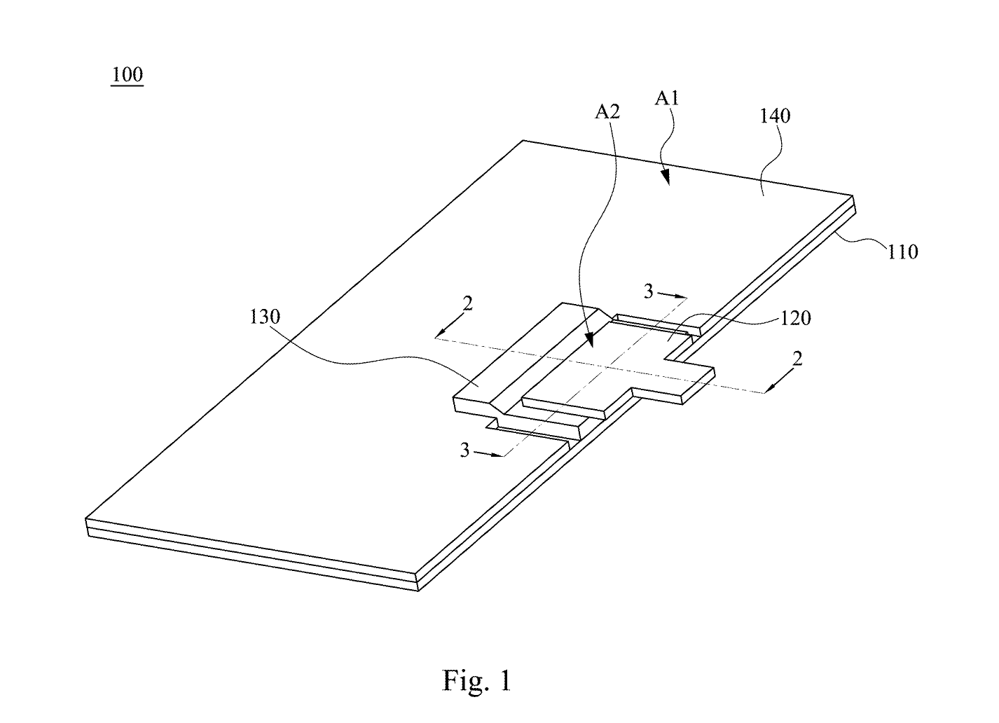

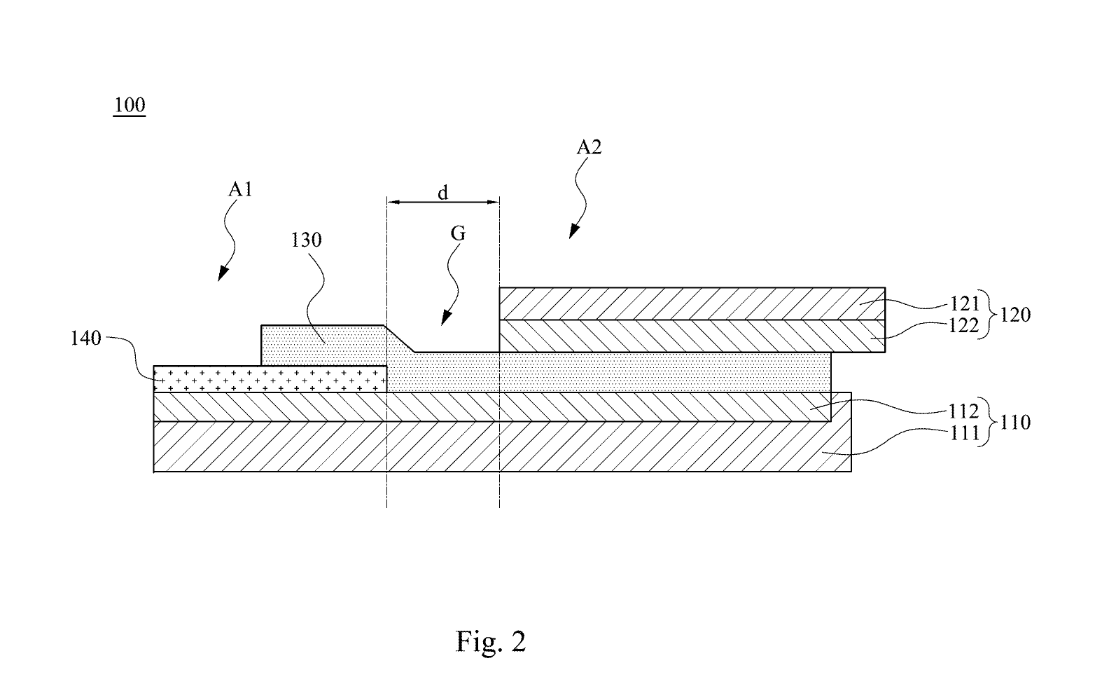

The present disclosure provides a printed circuit board connecting structure, which includes several advantages, such as simplifying manufacturing process of the printed circuit board connecting structure, materials used in the manufacturing process are reduced, and the registration tolerance in the manufacturing process is improved. In addition, the printed circuit board connecting structure is also possessed with properties such as water proof and air proof. The elements of the printed circuit board connecting structure and the relationship between each element are described below with reference made to FIG. 1 and FIG. 2.

FIG. 1 illustrates a top view of a printed circuit board connecting structure 100 according to an embodiment of the present disclosure. FIG. 2 illustrates a cross-sectional view along line 2-2 in FIG. 1. As shown in FIG. 1 and FIG. 2, the printed circuit board connecting structure 100 includes a first printed circuit board 110, a second printed circuit board 120, an ACF (anisotropy conductive film) 130, and a protection layer 140. First printed circuit board 110 includes a first substrate 111 and a first circuit 112 located on the first substrate 111. The second printed circuit board 120 includes a second substrate 121 and a second circuit 122 located on the second substrate 121. The first circuit 112 and the second circuit 122 face towards each other, and the second printed circuit board 120 partially covers the first printed circuit board 110.

As shown in FIG. 2, the ACF 130 is disposed between the first printed circuit board 110 and the second printed circuit board 120. In particular, the ACF 130 is disposed between the first circuit 112 and the second circuit 122. The ACF 130 only permits current to flow along a direction from the first printed circuit board 110 to the second printed circuit board 120, or from the second printed circuit board 120 to the first printed circuit board 110 (that is the upside-down direction in FIG. 2), and thus the current is not permitted to flow in a direction perpendicular to the aforementioned direction. By the foregoing disposition, the first circuit 112 of the first printed circuit board 110 may transmit an electrical signal to the second circuit 122 of the second printed circuit board 120 via the ACF 130, and thus the first printed circuit board 110 and the second printed circuit board 120 are electrically connected.

In addition, the protection layer 140 partially covers the first printed circuit board 110. In particular, the protection layer 140 covers a portion of the first circuit 112 on the first printed circuit board 110 at a place that the first circuit 112 is not covered by the second printed circuit board 120. An area on the first circuit 112 of the first printed circuit board 110 that is covered by the protection layer 140 is defined as a first area A1 herein, and an area on the first circuit 112 of the first printed circuit board 110 that is not covered by the protection layer 140 is defined as a second area A2. In the present embodiment, by disposing the protection layer 140 on the first area A1 not covered by the second printed circuit board 120, the first area A1 of the first circuit 112 is isolated from the air and thus well protected.

In the printed circuit board connecting structure 100 of the present embodiment, the second area A2 of the first circuit 112 is adjacent to a side of the first printed circuit board 110. Please refer to FIG. 1, the second area A2 of the first circuit 112 is extended to a side of the first printed circuit board 110. In some embodiments, the second area A2 may be located at a corner of the first printed circuit board 110. In some embodiments, the second area A2 may be located at a center of the first printed circuit board 110. People skilled in the art may arbitrarily disposed the second area A2 at different locations, as long as the second printed circuit board 120 may be attached to the first printed circuit board 110 in the second area A2.

As shown in FIG. 2, the second area A2 is not entirely covered by the second printed circuit board 120. Specifically, the orthogonal projection of the second printed circuit board 120 on the first printed circuit board 110 is spaced apart from the protection layer 140 at a distance d. In other words, there is a gap G sandwiched between the second printed circuit board 120 and the protection layer 140. When the second printed circuit board 120 is going to be attached on the first printed circuit board 110, the gap G may function as a buffer space, which improves the registration tolerance.

As shown in FIG. 2, a portion of the first circuit 112 at the gap G is neither covered by the second printed circuit board 120 nor the protection layer 140. Instead, the ACF 130 covers the gap G. The ACF 130 may isolate the first circuit 112 under the gap G from the environment. In the present embodiment, the ACF 130 is designed with water proof and air proof properties to achieve a better protection effect. For example, the ACF 130 may be made of a material including thermosetting resin. People with ordinary skill in the art may change materials of the ACF 130 to achieve various protection effects according to practical needs.

In sum, the ACF 130 is located between the first printed circuit board 110 and the second printed circuit board 120 to transmit the current, and the ACF 130 also covers the first circuit 112 at the gap G to protect the first circuit 112. In other words, in the direction along the line 2-2. The ACF 130 entirely convers the second area A2 of the first circuit 112. By setting the protection layer 140 to cover the first area A1 of first circuit 112, and setting the ACF 130 to entirely convers the second area A2 of the first circuit 112, all the area of the first circuit 112 on the first printed circuit board 110 are protected. By setting the foregoing configuration, when the printed circuit board connecting structure 100 are exposed in the environment, the printed circuit board connecting structure 100 is hardly to be damaged.

As shown in FIG. 2, besides covering the second area A2 of the first circuit 112, the ACF 130 further extends to the protection layer 140. Specifically, the ACF 130 extends to a surface of the protection layer 140 distal to the first circuit 112. In other words, a portion of the protection layer 140 is located between the ACF 130 and the first printed circuit board 110. As such, exterior materials are difficult to pass between the protection layer 140 and the ACF 130 and go into the gap G, and thus the first circuit 112 of the first printed circuit board 110 would not be affected by the exterior materials. By the foregoing configuration, one should not worry that the ACF 130 fails to entirely cover the second area A2 of the first circuit 112. In addition, in the manufacturing process of the printed circuit board connecting structure 100, it is not required to dispose the ACF 130 exactly in the second area A2, some portion of the ACF 130 may extend above the first area A1. The ACF 130 may arbitrarily extend to the protection layer 140, and the overall functionality of the printed circuit board connecting structure 100 is not affected.

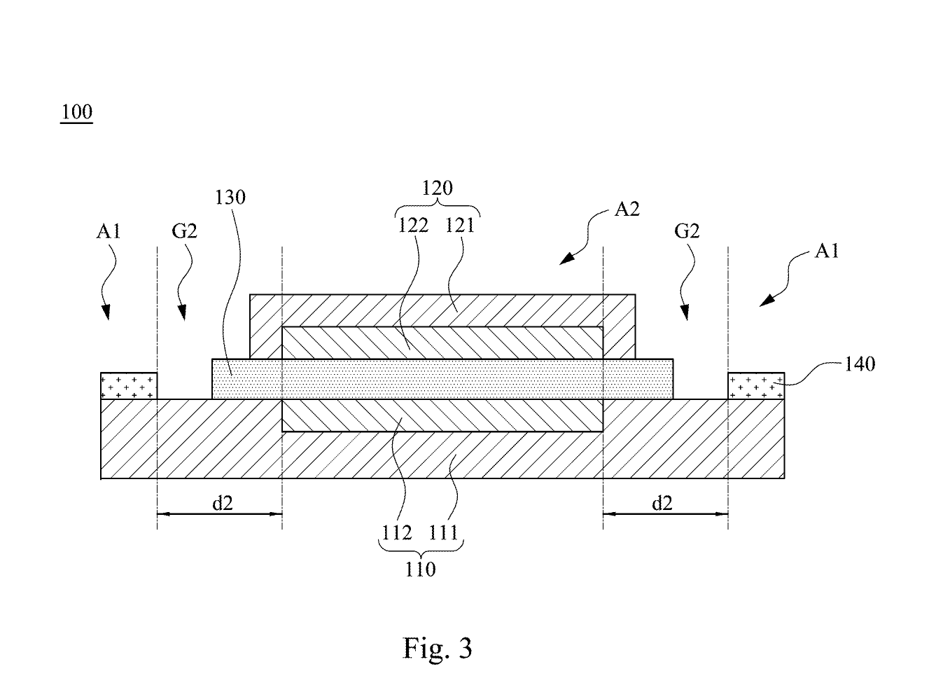

Please refer to FIG. 1, in the printed circuit board connecting structure 100 of the present embodiment, the second area A2 is a rectangular. The ACF 130 is extended to the protection layer 140 from a side of the rectangular. The first circuit 112 extends from the first area A1 to the second area A2 through the side of the rectangular, and the first circuit 112 doesn't extend from the first area A1 to the second area A2 through other two sides of the rectangular. Specifically, please refer to FIG. 3, which illustrates a cross-sectional view along line 3-3 in FIG. 1.

As shown in FIG. 3, the second area A2 of the first circuit 112 of the first printed circuit board 110 is not connected to the first area A1 of the first circuit 112 through the two sides of the second area A2, and thus along the direction of line 3-3, each side of the second area A2 of the first circuit 112 is spaced apart from the protection layer 140 at a distance d2. Since the distance d2 is preserved, the ACF 130 is not required to extend to the protection layer 140 along the direction of line 3-3, to assured that the second area A2 of the first circuit 112 is entirely covered. In other words, two second gaps G2 are sandwiched between two sides of the protection layer 140 and the ACF 130. Along the direction of line 3-3, the ACF 130 may entirely cover the second area A2 of the first circuit 112 between the two second gaps G2, and thus the ACF 130 is not required to extend to the protection layer 140.

It should be understood that the trace of the first circuit 112 should be taken into consideration to decide whether the ACF 130 should extend to the protection layer 140 at the junction between the first area A1 and the second area A2. In some embodiments, the second area A2 of the first circuit 112 is connected to a side of the first area A1 of the first circuit 112, and thus the embodiment shown in FIG. 2 may be implemented to that side to achieve better protection. If the second area A2 of the first circuit 112 is not connected to a side of the first area A1 of the first circuit 112, and then the embodiment shown in FIG. 3 may be implemented to reduce material cost. The structures shown in FIG. 2 and FIG. 3 may be adopted according to practical needs. For example, the ACF 130 shown in FIG. 3 may extend to the protection layer 140 along direction of the line 3-3 to provide protection to the first substrate 111.

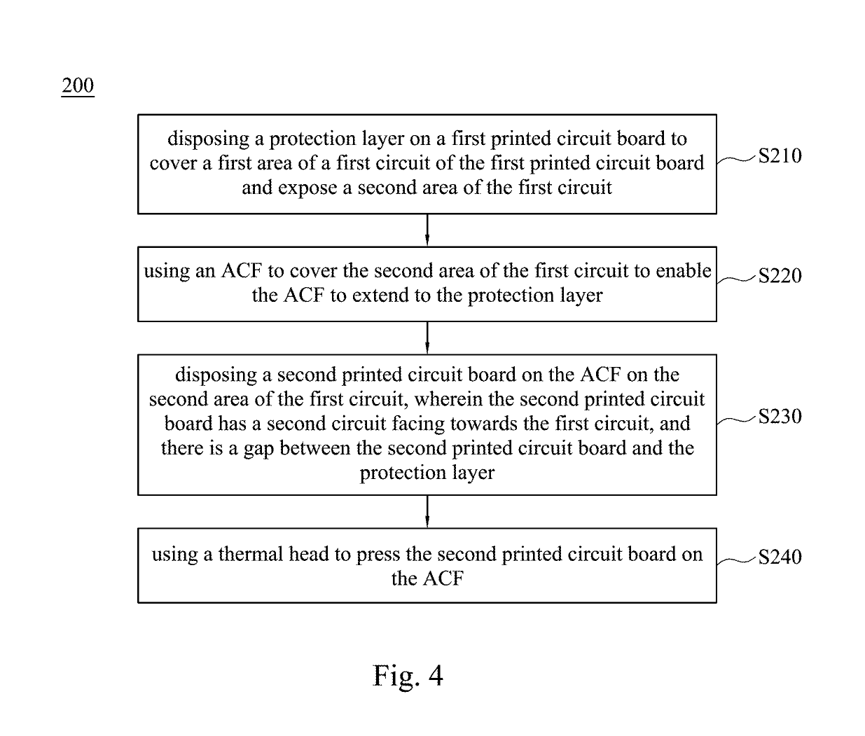

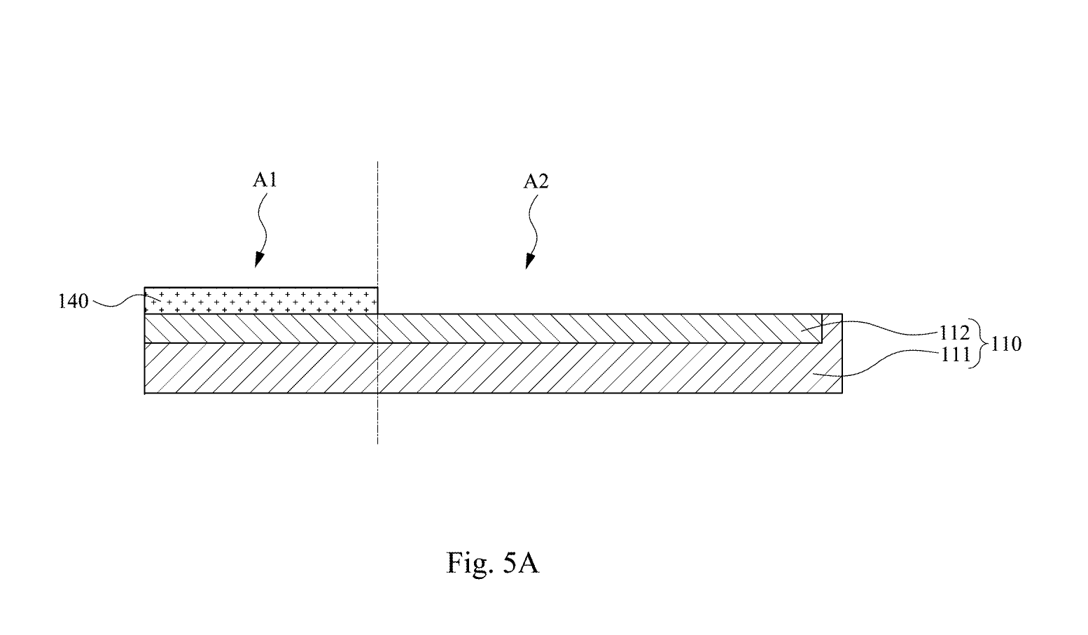

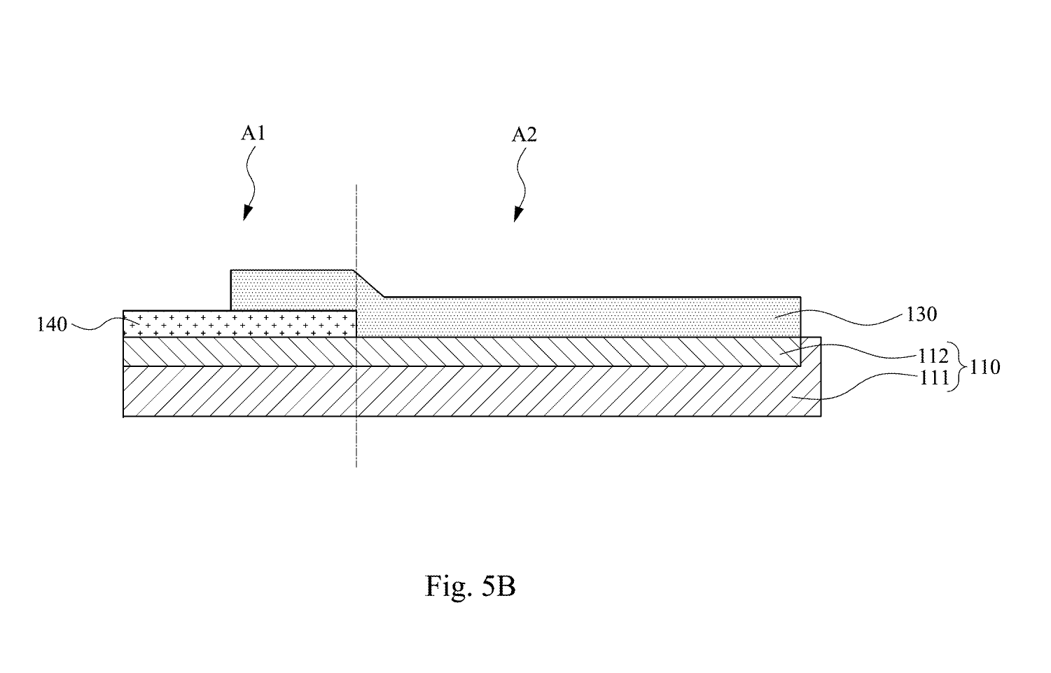

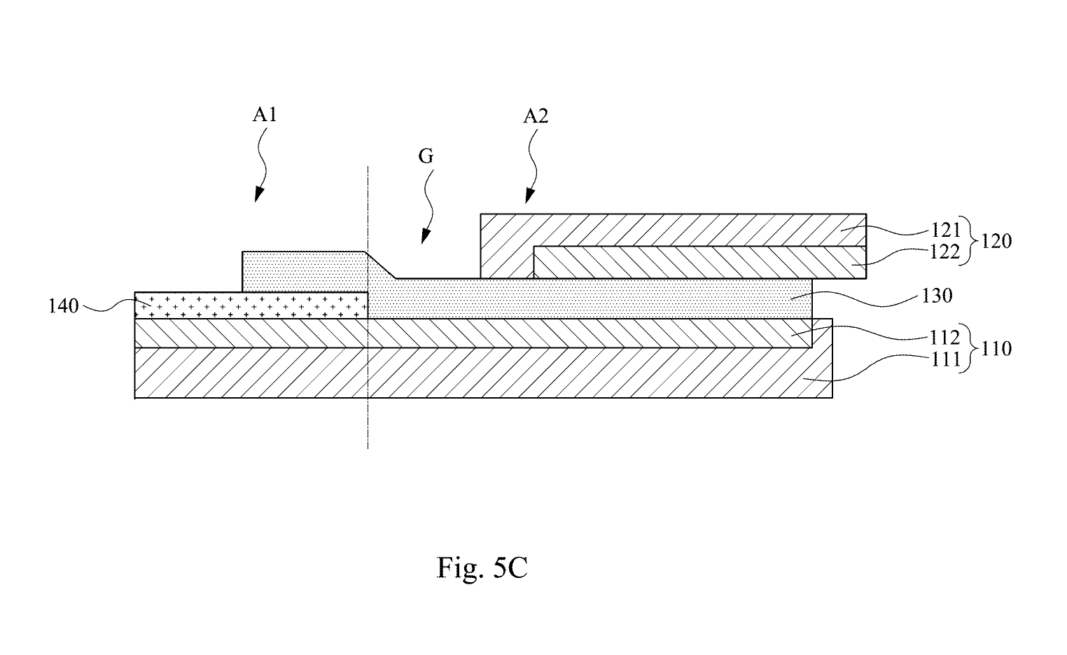

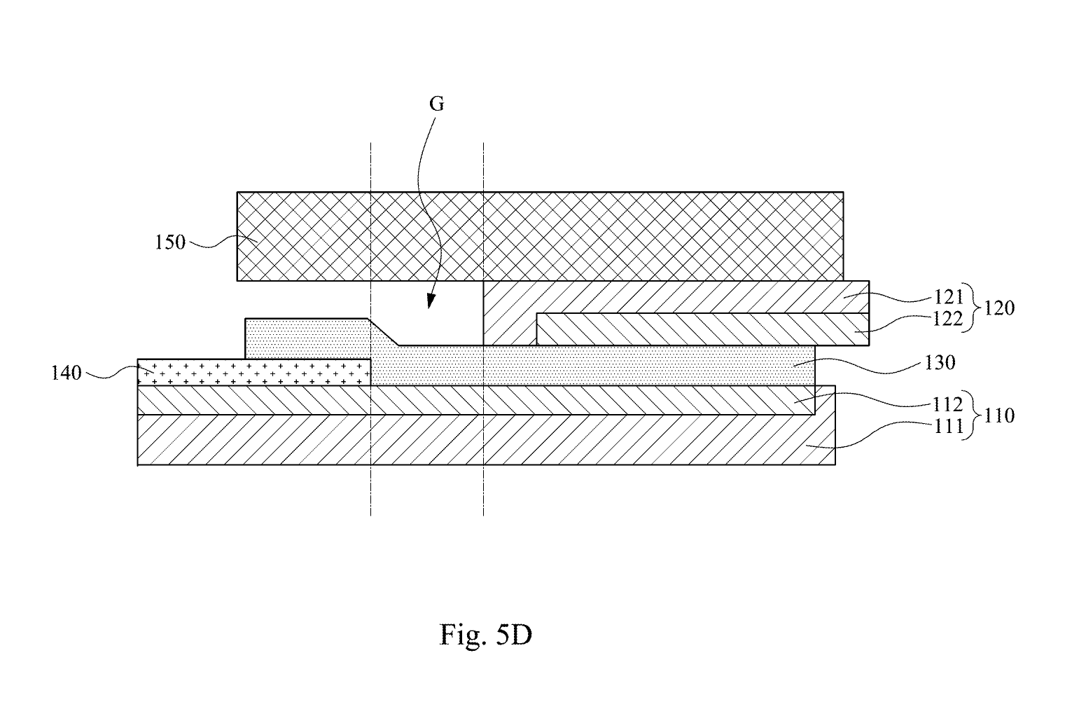

In sum, the elements of the printed circuit board connecting structure 100 and the relationship between each element are briefly introduced above. As follow, a method of manufacturing the printed circuit board connecting structure 100 will be introduced with reference made to FIG. 4 and FIG. 5A to FIG. 5D.

Please refer to FIG. 4 and FIG. 5A to FIG. 5D. FIG. 4 illustrates a flow diagram of a method 200 of bonding printed circuit board connecting structure 100 shown in FIG. 1. FIG. 5A to FIG. 5D illustrates a cross-sectional view of the printed circuit board connecting structure 100 shown in FIG. 1 along line 2-2 in various steps of the method 200 shown in FIG. 4. As shown in FIG. 4, the method 200 includes step S210 to step S240.

First, processing with step S210. As shown in FIG. 5A, in step S210, a protection layer 140 is disposed on a first printed circuit board 110 having a first circuit 112, and make the protection layer 140 cover a first area A1 of the first circuit 112 of the first printed circuit board 110, and expose a second area A2 of the first circuit 112. The definition of first area A1 and second area A2 is discussed above and thus not repeat herein.

Then processing with step S220. As shown in FIG. 5B, in step S220, an ACF 130 is covered on the second area A2 of the first circuit 112, and make the ACF 130 extend to the protection layer 140. In step S220, the ACF 130 may cover the second area A2 without great precision, portion of the ACF 130 may extend to the protection layer 140 to cover the first area A1, and thus achieves a better registration tolerance, a better protection effect, and the cost is reduced.

Then processing with step S230. As shown in FIG. 5C, in step S230, a second printed circuit board 120 is disposed on the ACF 130 on the second area A2 of first printed circuit board 110. The second printed circuit board 120 has a second circuit 122, the second circuit 122 faces the first circuit 112 of the first printed circuit board 110. A gap G is sandwiched between the second printed circuit board 120 and the protection layer 140. Since the gap G is preserved, the protection layer 140 will not interfere with the disposing of the second printed circuit board 120 on the first printed circuit board 110. In other words, there is a better registration tolerance to stack the second printed circuit board 120 on the first printed circuit board 110.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

1. A printed circuit board connecting structure, comprising:
a first printed circuit board having a first circuit;
a protection layer covering a first area of the first circuit;
an anisotropy conductive film (ACF) covering a second area of the first circuit and extending to the protection layer in a first direction; and
a second printed circuit board having a second circuit facing the first circuit, and partially overlapping with the ACF on the second area of the first circuit, wherein there is a first gap between the second printed circuit board and the protection layer, and the first gap extends along the first direction, and wherein there is a second gap between the ACF and the protection layer, and the second gap extends along a second direction that is substantially perpendicular to the first direction.

2. The printed circuit board connecting structure of claim 1, wherein the second area of the first circuit extends to a side of the first printed circuit board.

3. The printed circuit board connecting structure of claim 1, wherein an orthogonal projection of the second printed circuit board on the first printed circuit board is spaced apart from the protection layer at a distance.

4. The printed circuit board connecting structure of claim 1, wherein the protection layer is located between the ACF and the first area of the first circuit.

5. The printed circuit board connecting structure of claim 1, wherein the ACF is located between the second circuit and the second area of the first circuit.

6. The printed circuit board connecting structure of claim 1, wherein the ACF is made of a material comprising thermosetting resin.

7-10. (canceled)
